(19) United States
(12) Patent Application Publication
(10) Pub. No.: US 2025/0338486 A1
(43) Pub. Date: Oct. 30, 2025

(54) SEMICONDUCTOR DEVICE AND METHOD FOR FABRICATING THE SAME

(71) Applicant: SK hynix Inc., Gyeonggi-do (KR)

(72) Inventors: Beomyoung KIM, Gyeonggi-do (KR); Jihoon KIM, Gyeonggi-do (KR); Kyung Sun RYU, Gyeonggi-do (KR); Jaesuk CHOI, Gyeonggi-do (KR)

(21) Appl. No.: 18/955,981

(22) Filed: Nov. 22, 2024

(30) Foreign Application Priority Data
Apr. 24, 2024 (KR) 10-2024-0054562

(51) Int. Cl. H10B 12/00

(52) U.S. Cl. CPC H10B 12/485; H10B 12/0335; H10B 12/05; H10B 12/315; H10B 12/482; H10D 64/027; H10D 64/513; H10D 64/68

(57) ABSTRACT

A semiconductor device includes a semiconductor substrate; an active region including an isolation layer formed in the semiconductor substrate and a protrusion defined by the isolation layer, and disposed at a higher level than an upper surface of the isolation layer; first and second pads suitable for covering the protrusion of the active region; a first contact formed in an upper portion of the first pad and a conductive structure in an upper portion of the first contact; and a second contact formed in an upper portion of the second pad.

### CROSS-REFERENCE TO RELATED APPLICATIONS

The present application claims priority under 35 U.S.C 119 (a) to Korean Patent Application No. 10-2024-0054562, filed on Apr. 24, 2024, which is incorporated herein by reference in its entirety.

### BACKGROUND

### 1. Field

Embodiments of the present invention relate generally to a semiconductor device and a method for fabricating the same and, more particularly, to a semiconductor device including a buried gate, and a method for fabricating the semiconductor device.

### 2. Description of the Related Art

As semiconductor devices become more integrated, their active regions are also shrinking, causing an issue of decreased contact margins. Hence, new solutions are needed for enhanced performance characteristics and reliability.

### SUMMARY

Embodiments of the present invention are directed to a semiconductor device capable of securing a contact margin, and a method for fabricating the semiconductor device.

Embodiments of the present invention are directed to a semiconductor device capable of improving the electrical characteristics of a device, and a method for fabricating the semiconductor device.

In accordance with an embodiment of the present invention, a semiconductor device includes a semiconductor substrate; an active region including an isolation layer formed in the semiconductor substrate and a protrusion defined by the isolation layer, and disposed at a higher level than an upper surface of the isolation layer; first and second pads suitable for covering the protrusion of the active region; a first contact formed in an upper portion of the first pad and a conductive structure in an upper portion of the first contact; and a second contact formed in an upper portion of the second pad.

In accordance with another embodiment of the present invention, a semiconductor device includes a semiconductor substrate; an active region including an isolation layer which is formed in the semiconductor substrate and a protrusion which is defined by the isolation layer, spaced apart from another protrusion by the isolation layer, and disposed at a higher level than an upper surface of the isolation layer; a buried gate structure formed in the semiconductor substrate to cross the isolation layer and the active region and have an upper surface at a lower level than the protrusion of the active region; first and second pads suitable for covering the protrusion of the active region; a first contact formed in an upper portion of the first pad and a conductive structure in an upper portion of the first contact; and a second contact formed in an upper portion of the second pad.

In accordance with another embodiment of the present invention, a semiconductor device includes a semiconductor substrate; a bit line contact and a bit line structure formed in an upper portion of the substrate; a bit line pad disposed between the substrate and the bit line contact; a storage node contact disposed spaced apart from the bit line structure in the upper portion of the substrate; and a storage node pad disposed between the substrate and the storage node contact.

In accordance with another embodiment of the present invention, a method for fabricating a semiconductor device includes defining an active region in a substrate, the active region including an isolation layer and a protrusion which is disposed spaced apart from another protrusion by the isolation layer at a higher level than an upper surface of the isolation layer; forming first and second pads suitable for covering the protrusion of the active region; forming the isolation layer between the first pad and the second pad, and a low-k layer over the first and second pads; forming a first contact hole that exposes the first pad by penetrating the low-k layer over the first pad; sequentially forming a first contact and a conductive structure over the first pad in the first contact hole; forming a second contact hole that exposes the second pad by penetrating the low-k layer over the second pad; and forming a second contact suitable for gap-filling the second contact hole.

These and other features and advantages will become better understood from the following detailed description of embodiments in conjunction with the accompanying drawings.

### BRIEF DESCRIPTION OF THE DRAWINGS

FIG. 1 is a plan view illustrating a semiconductor device in accordance with an embodiment of the present invention.

FIGS. 2A and 2B are cross-sectional views respectively illustrating a semiconductor device in accordance with an embodiment of the present invention.

FIGS. 3A, 4A, 5A, 6A, 7A, 8A, 9A, 10A, 11A, 12A, 13A, 14A, 15A, and 16A are cross-sectional views illustrating a method for fabricating the semiconductor device shown in FIG. 2A in accordance with an embodiment of the present invention.

FIGS. 3B, 4B, 5B, 6B, 7B, 8B, 9B, 10B, 11B, 12B, 13B, 14B, 15B, and 16B are cross-sectional views illustrating a method for fabricating the semiconductor device shown in FIG. 2B in accordance with an embodiment of the present invention.

FIGS. 17A and 17B are cross-sectional views illustrating semiconductor devices in accordance with another embodiment of the present invention.

FIGS. 18A, 19A, 20A, 21A, 22A, 23A, 24A, 25A, 26A, 27A, 28A, 29A, 30A and 31A are cross-sectional views illustrating a method for fabricating the semiconductor device shown in FIG. 17A in accordance with yet another embodiment of the present invention.

FIGS. 18B, 19B, 20B, 21B, 22B, 23B, 24B, 25B, 26B, 27B, 28B, 29B, 30B and 31B are cross-sectional views illustrating a method for fabricating the semiconductor device shown in FIG. 17B in accordance with yet another embodiment of the present invention.

FIG. 32 is a plan view illustrating a semiconductor device in accordance with another embodiment of the present invention.

FIG. 33 is a cross-sectional view illustrating the semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly over the second layer or the substrate but also a case where a third layer exists between the first layer and the second layer or the substrate.

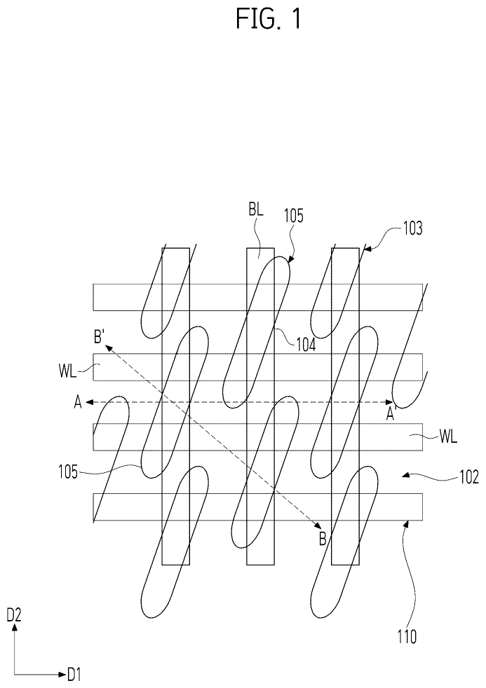

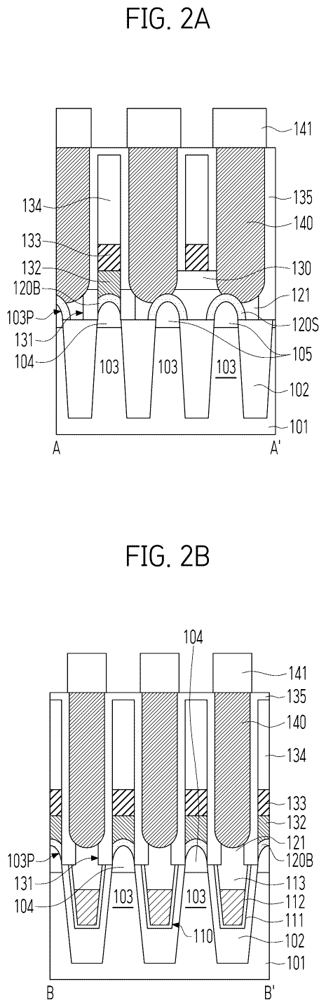

FIG. 1 is a plan view illustrating a semiconductor device in accordance with an embodiment of the present invention. FIGS. 2A and 2B are cross-sectional views illustrating a semiconductor device in accordance with an embodiment of the present invention. FIG. 2A is a cross-sectional view taken along a line A-A′ shown in FIG. 1. FIG. 2B is a cross-sectional view taken along a line B-B′ shown in FIG. 1.

Referring to FIGS. 1, 2A, and 2B, the semiconductor device may include a plurality of memory cells. Each memory cell may include conductive structures that are disposed at different levels. For example, each memory cell may include a cell transistor including a buried word line WL, a bit line BL 133, and a memory element 141 (see FIGS. 2A and 2B).

An isolation layer 102 and an active region 103 may be formed in a substrate 101. A plurality of active regions 103 may be defined by the isolation layer 102. Each active region 103 may have a bar shape having a long axis and a short axis. The active regions 103 may be disposed spaced apart from each other by a predetermined interval. Each active region 103 may have an upper surface at a higher level than an upper surface of the isolation layer 102. Each active region 103 may include a protrusion 103P disposed at a higher level than the upper surface of the isolation layer 102.

The substrate 101 may include a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include another semiconductor material, such as germanium. The substrate 101 may include a III/V-group semiconductor substrate, for example, a compound semiconductor substrate, such as gallium arsenide (GaAs). The substrate 101 may also include a Silicon-On-Insulator (SOI) substrate.

A line-shaped buried word line WL extending in a first direction D1 may be formed in the substrate 101. The buried word line WL may be formed of a buried gate structure. The buried gate structure may include a gate electrode 112 and a gate capping layer 113 that are formed over a gate dielectric layer 111 formed on the surface of a gate trench 110 to fill the gate trench 110.

To be specific, the line-shaped gate trench 110 may be formed in the substrate 101 in the first direction D1 to cross the active region 103 and the isolation layer 102. The lower surface of the gate trench 110 may be disposed at a higher level than the lower surface of the isolation layer 102. The gate trench 110 may have a shallower depth than the isolation layer 102. According to another embodiment of the present invention, the lower portion of the gate trench 110 may have a curvature. According to another embodiment of the present invention, the isolation layer 102 formed in the direction that the gate trench 110 extends may be etched to a predetermined depth to form a fin in the active region 103.

The gate dielectric layer 111 may be formed on the surface of the gate trench 110. The gate electrode 112 filling a portion of the gate trench 110 may be formed over the gate dielectric layer 111. The gate capping layer 113 may be formed over the gate electrode 112 to fill the remaining portion of the gate trench 110. The upper surface of the gate capping layer 113 may be disposed at a higher level than the upper surface of the isolation layer 102.

The gate dielectric layer 111 may be conformally formed on the lower surface and inner surfaces of the gate trench 110. The gate dielectric layer 111 may include silicon oxide, silicon nitride, silicon oxynitride, a high-k material, or a combination thereof. The high-k material may include a material whose dielectric constant is greater than the dielectric constant of silicon oxide. For example, the high-k material may include a material having a greater dielectric constant than approximately 3.9. For another example, the high-k material may include a material having a greater dielectric constant than approximately 10. For yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. Other known high-k materials may selectively be used as the high-k material. The gate dielectric layer 111 may include a metal oxide.

The gate electrode 112 may have a shape that fills the lower portion of the gate trench 110. The gate electrode 112 may be a low-resistance material to reduce the gate sheet resistance. The gate electrode 112 may include a semiconductor material, a metal-based material, or a combination thereof. The gate electrode 112 may include polysilicon, a metal, a metal nitride, or a combination thereof. For example, the gate electrode 112 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present invention, the gate electrode 112 may be formed of titanium nitride alone or molybdenum alone. According to yet another embodiment of the present invention, the gate electrode 112 may be formed of a stack of titanium nitride and tungsten (i.e., TiN/W) or a stack of titanium nitride and polysilicon (i.e., TiN/Polysilicon).

According to another embodiment of the present invention, the gate electrode 112 may apply a dual gate structure including upper and lower gates. According to yet another embodiment of the present invention, the gate electrode 112 may apply a triple gate structure including upper, middle, and lower gates.

According to another embodiment of the present invention, the gate electrode 112 may have a high work function. Here, the high work function may refer to a work function which is greater than the mid-gap work function of silicon. A low work function may refer to a work function which is less than the mid-gap work function of silicon. To be specific, the high work function may have a work function which is greater than approximately 4.5 eV, and the low work function may have a work function which is less than approximately 4.5 eV. The gate electrode 112 may include P-type polysilicon or nitrogen-rich titanium nitride (TiN).

According to another embodiment of the present invention, the gate electrode 112 may have an increased high work function. The gate electrode 112 may include a metal silicon nitride. The metal silicon nitride may be a metal nitride that is doped with silicon. The gate electrode 112 may include a metal silicon nitride having a controlled silicon content. For example, the gate electrode 112 may include tantalum silicon nitride (TaSiN) or titanium silicon nitride (TiSiN). Titanium nitride may have a high work function, and silicon may be contained in the titanium nitride to further increase the work function of the titanium nitride. The titanium silicon nitride may have a controlled silicon content to have an increased high work function. According to another embodiment of the present invention, the gate electrode 112 may include titanium aluminum nitride (TiAlN).

The gate capping layer 113 may serve to protect the gate electrode 112. The gate capping layer 113 may fill the upper portion of the gate trench 110 over the gate electrode 112. The gate capping layer 113 may include a dielectric material. The gate capping layer 113 may include silicon nitride, silicon oxynitride, or a combination thereof. According to another embodiment of the present invention, the gate capping layer 113 may include a combination of silicon nitride and silicon oxide. The gate capping layer 113 may include a silicon nitride liner and a Spin-On-Dielectric (SOD) material.

First and second impurity regions 104 and 105 may be formed over the substrate 101. The first and second impurity regions 104 and 105 may be referred to as ‘first and second source/drain regions’. The first and second impurity regions 104 and 105 may be formed in a protrusion 103P of the active region. The lower portions of the first and second impurity regions 104 and 105 may be disposed at a higher level than the upper surface of the gate electrode 112, but the embodiments of the present invention are not limited thereto. The gate electrode 112 and the first and second impurity regions 104 and 105 may become a cell transistor. The cell transistor may improve the short channel effect by the gate electrode 112 having a buried gate structure.

First and second pads 120B and 120S may be formed in the upper portions of the first and second impurity regions 104 and 105. The first and second pads 120B and 120S may be applied to secure a contact margin with the substrate during a subsequent contact process. The first pad 120B may be disposed in the upper portion of the first impurity region 104. The second pad 120S may be disposed in the upper portion of the second impurity region 105.

The first and second pads 120B and 120S may include a semiconductor material. The first and second pads 120B and 120S may be selective epitaxial growth (SEG) layers. The first and second pads 120B and 120S may be doped SEG materials. The first and second pads 120B and 120S may be formed simultaneously through a one-time process.

A low-k layer 121 may be disposed between the first pad 120B and the second pad 120S. The low-k layer 121 may have a lower dielectric constant than silicon nitride (Si₃N₄). The low-k layer 121 may include a material layer having a lower dielectric constant than approximately 3.9. For example, the low-k layer 121 may include SiCO (carbon incorporated silicon oxide). The low-k layer 121 may also be disposed over the first and second pads 120B and 120S. The upper surface of the low-k layer 121 may be disposed at a higher level than the upper surfaces of the first and second pads 120B and 120S.

A hard mask 130 may be formed over the low-k layer 121. The hard mask 130 may serve as an etching mask for forming the first contact hole 131. The hard mask 130 may include a material having an etching selectivity with respect to the low-k layer 121. The hard mask 130 may be disposed below the first conductive line 133 disposed between the second contacts 140.

The first contact 132 may be formed over the first pad 120B. The first contact 132 may be coupled to the first impurity region 104 through the first pad 120B. The first pad 120B may improve the contact margin between the first contact 132 and the first impurity region 104. The first pad 120B may have the same line width as that of the first contact 132 and may have both sidewalls aligned in a direction perpendicular to the substrate. The first contact 132 may be disposed in the first contact hole 131 whose lower surface is lower than the upper surface of the active region 103. A portion of the first contact 132 may have a line width which is less than the diameter of the first contact hole 131. The first contact 132 may include a conductive material. For example, the first contact 132 may be formed of polysilicon or a metal material. The first contact 132 may be referred to as a ‘bit line contact 132’. The first pad 120B may be referred to as a ‘bit line contact pad 120B’.

A conductive structure may be formed in the upper portion of the first contact 132. The conductive structure may be referred to as a ‘bit line structure’. The conductive structure may include a stacked structure of a conductive line 133 and a conductive line hard mask 134. The conductive line 133 may be coupled to the first impurity region 104 by the first contact 132 and the first pad 120B.

The conductive line 133 and the conductive line hard mask 134 may be of a line type extending in a second direction D2 shown in FIG. 1. The conductive structures may be disposed spaced apart from each other in the first direction D1. A portion of the conductive line 133 may be coupled to the first contact 132. The line width of the conductive line 133 may be the same as the line width of the first contact 132. Therefore, the conductive line 133 may extend in one direction while covering the upper surface of the first contact 132. The conductive line 133 may include a metal material. The conductive line hard mask 134 may include a dielectric material. The conductive line 133 and the conductive line hard mask 134 may be referred to as ‘a bit line 133 and a bit line hard mask 134,’ respectively. The conductive line 133 may correspond to the bit line BL shown in FIG. 1.

Spacers 135 may be formed on the sidewalls of the first pad 120B, the first contact 132, and the conductive structure 131, 134. The spacers 135 may gap-fill the first contact hole 131, that is, on the sidewalls of the first pad 120B and the first contact 132, and the spacers 135 may also be formed on the sidewalls of the conductive line 133 and the conductive line hard mask 134. The spacers 135 may be formed as a continuous single layer. The spacers 135 may include, for example, silicon nitride.

According to another embodiment of the present invention, the spacers 135 may include a spacer structure. For example, the spacer structure may include one selected from the group including silicon nitride, silicon oxide, silicon oxynitride, low-k materials and combinations thereof. The spacer structure may include a spacer 135 gap-filling the first contact hole 131, and a spacer 135 disposed on the sidewalls of the conductive line 133 and the conductive line hard mask 134. The spacer 135 gap-filling the first contact hole 131 may be referred to as a ‘gap-fill spacer’. The spacer 135 disposed on the sidewalls of the conductive line 133 and the conductive line hard mask 134 may be referred to as a ‘bit-line spacer’. The bit-line spacer 134 may be a single layer or multiple layers. According to another embodiment of the present invention, the spacers 135 may further include a low-k material or an air gap.

A second contact 140 may be disposed between the neighboring conductive structures. The second contact 140 may have a pillar shape. The second contact 140 may be disposed over the second pad 120S. The second contact 140 may be coupled to the second impurity region 105 through the second pad 120S. The second pad 120S may improve the contact margin between the second contact 140 and the second impurity region 105. The second contact 140 may include a conductive material, such as, for example, a semiconductor material, or a metal material. For example, the semiconductor material may include polysilicon. For example, the metal material may include tungsten (W). According to another embodiment of the present invention, the second contact 140 may include a stacked structure of a semiconductor material and a metal material. According to yet another embodiment of the present invention, the second contact 140 may include a stacked structure of a semiconductor material, an ohmic contact layer, and a metal material. The second contact 140 may be referred to as a ‘storage node contact 140’.

Referring to FIG. 2A, a spacer 135 and a low-k layer 121 may be disposed between the first pad 120B and the second pad 120S. Therefore, parasitic capacitance and leakage current between the conductive structure coupled to the first pad 120B and the second contact 140 coupled to the second pad 120S may be prevented.

As described above, according to an embodiment of the present invention, the contact margin (or landing margin) between each contact and the substrate 101 may be secured by disposing the first and second pads 120B and 120S below the first and second contacts 132 and 140. By forming the first and second pads 120B and 120S to cover the active region protrusion 130P over the active region protrusion 130P, there is an effect of increasing the line width of the active region. Therefore, an overlap margin between the first and second contacts 132 and 140 and the substrate may be secured. Also, since the etching height of the contact hole for forming each contact may be decreased as much as the height of the first and second pads 120B and 120S, it is possible to prevent a not-open phenomenon of the contact hole and secure the process margin.

Also, according to the embodiment of the present invention, it is possible to prevent the parasitic capacitance and leakage current between the contacts and prevent a short between the contacts by applying the low-k layer 121 between the active region protrusion 130P and the first and second pads 120B and 120S.

A memory element 141 may be formed over the second contact 140. The memory element 141 may include a capacitor including a storage node. The storage node may include a pillar shape, but the embodiments of the present invention are not limited thereto. Although not illustrated, a dielectric layer and a plate node may be further formed over the storage node. The storage node may also have a cylinder shape other than the pillar shape. According to another embodiment of the present invention, a landing pad may be disposed between the second contact 140 and the memory element 141. The landing pads may be spaced apart from each other by an inter-layer dielectric layer.

According to another embodiment of the present invention, diverse memory elements may be coupled to the second contact 140 over the second contact 140.

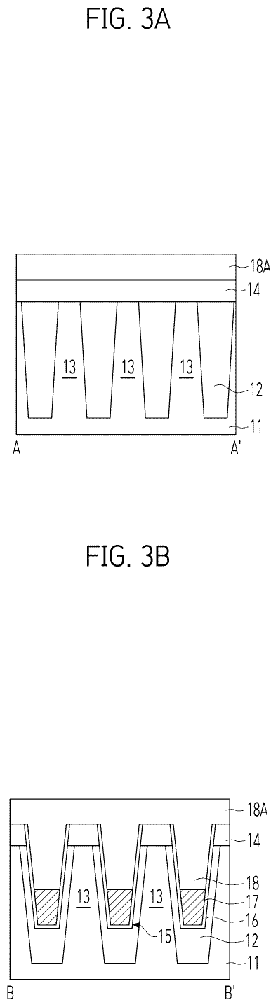

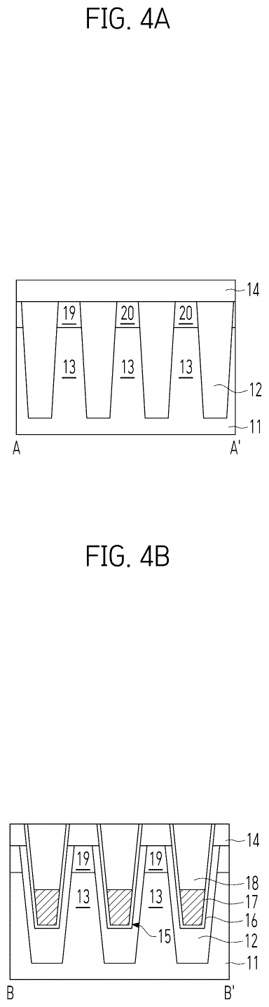

FIGS. 3A, 4A, 5A, 6A, 7A, 8A, 9A, 10A, 11A, 12A, 13A, 14A, 15A, and 16A are cross-sectional views illustrating a method for fabricating the semiconductor device shown in FIG. 2A in accordance with an embodiment of the present invention. FIGS. 3B, 4B, 5B, 6B, 7B, 8B, 9B, 10B, 11B, 12B, 13B, 14B, 15B, and 16B are cross-sectional views illustrating a method for fabricating the semiconductor device shown in FIG. 2B in accordance with an embodiment of the present invention. FIGS. 3A and 3B show the same process, and are only different in the directions of the cross-sectional views. Similarly, FIGS. 4A and 4B to 16A and 16B also show the same processes, and are only different in the directions of the cross-sectional views. To help understanding, the cross-sectional views of the same process will be described together.

Referring to FIGS. 3A and 3B, an isolation layer 12 may be formed over a substrate 11. An active region 13 may be defined by the isolation layer 12. Referring to FIG. 1, each active region 13 may have a bar shape having a long axis and a short axis. The active regions 13 may be disposed spaced apart from each other by a predetermined interval.

The isolation layer 12 may be formed by a Shallow Trench Isolation (STI) process. The STI process may be performed as follows. The substrate 11 may be etched to form an isolation trench (reference symbol omitted). The isolation trench may be filled with a dielectric material, and as a result, the isolation layer 12 may be formed. The isolation layer 12 may include silicon oxide, silicon nitride, or a combination thereof. Chemical Vapor Deposition (CVD) or another deposition process may be performed to fill the isolation trench with a dielectric material. A planarization process, such as Chemical Mechanical Polishing (CMP), may be additionally performed.

Subsequently, a buried gate structure may be formed over the substrate 11. The buried gate structure may correspond to the word line WL illustrated in FIG. 1. Referring to FIG. 1, the buried gate structure may have a line type extending in the first direction D1. The buried gate structure may include a gate trench 15, a gate dielectric layer 16 covering the lower surface and sidewalls of the gate trench 15, a gate electrode 17 filling a lower portion of the gate trench 15 over the gate dielectric layer 16, and a gate capping layer 18 (see FIGS. 4A and 4B) formed over the gate electrode 17.

A method for forming the buried gate structure may be as follows.

First, the gate trench 15 may be formed in the substrate 11. The gate trench 15 may have a line shape crossing the active region 13 and the isolation layer 12. The gate trench 15 may be formed by forming a mask pattern (not shown) over the substrate 11 and performing an etching process with the mask pattern used as an etching mask. The gate trench 15 may be formed by using a hard mask layer 14 as an etching barrier. The hard mask layer 14 may include silicon oxide. The gate trench 15 may be formed to be shallower than the isolation trench. The lower surface of the gate trench 15 may be disposed at a higher level than the lower surface of the isolation layer 12. The depth of the gate trench 15 may have a sufficient depth to increase the average cross-sectional area of the gate electrode 17. Accordingly, the resistance of the gate electrode 17 may be decreased. According to another embodiment of the present invention, the bottom edges of the gate trench 15 may have a curvature. By forming the bottom edges of the gate trench 15 to have a curvature, the unevenness in the lower portion of the gate trench 15 may be minimized, and thus, the gate electrode 17 may be easily filled.

Although not illustrated, a fin region may be formed after the gate trench 15 is formed. The fin region may be formed by recessing a portion of the isolation layer 12.

Subsequently, a gate dielectric layer 16 may be formed on the lower surface and sidewalls of the gate trench 15. Before the gate dielectric layer 16 is formed, the etching damage on the surface of the gate trench 15 may be cured. For example, a sacrificial oxide may be formed by a thermal oxidation process, and then the sacrificial oxide may be removed.

The gate dielectric layer 16 may be formed by a thermal oxidation process. For example, the bottom and sidewalls of the gate trench 15 may be oxidized to form the gate dielectric layer 16.

According to another embodiment of the present invention, the gate dielectric layer 16 may be formed by a deposition method. For example, the gate dielectric layer 16 may be formed by Chemical Vapor Deposition (CVD) or Atomic Layer Deposition (ALD). The gate dielectric layer 16 may include a high-k material, an oxide, a nitride, an oxide-nitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, and a combination thereof. Other known high-k materials may be selectively used as the high-k material.

According to another embodiment of the present invention, the gate dielectric layer 16 may be formed by depositing a liner polysilicon layer and then radically oxidizing the liner polysilicon layer.

According to yet another embodiment of the present invention, the gate dielectric layer 16 may be formed by forming a liner silicon nitride layer and then radically oxidizing the liner silicon nitride layer.

Subsequently, a gate electrode 17 may be formed over the gate dielectric layer 16. The gate electrode 17 may be formed by forming a conductive layer (not shown) to fill the gate trench 15 and then performing a recessing process. The recessing process may be performed by performing an etch-back process, or sequentially performing a Chemical Mechanical Polishing (CMP) process and an etch-back process. The gate electrode 17 may have a recessed shape that fills a portion of the gate trench 15. The upper surface of the gate electrode 17 may be disposed at a lower level than the upper surface of the substrate 11. The gate electrode 17 may include a metal, a metal nitride, or a combination thereof. For example, the gate electrode 17 may include titanium nitride (TiN), tungsten (W), or a stack of titanium nitride/tungsten (TiN/W). The stack of titanium nitride/tungsten (TiN/W) may have a structure that is formed by conformally forming titanium nitride and then using tungsten to fill a portion of the gate trench 15. According to another embodiment of the present invention, the gate electrode 17 may be formed as a single structure of titanium nitride or a stacked structure of titanium nitride. According to another embodiment of the present invention, the gate electrode 17 may further include a work function control layer or a dipole inducing layer between the gate dielectric layer 16 and the gate electrode 17. According to yet another embodiment of the present invention, the gate electrode 17 may be formed as a stacked structure of heterogeneous materials. According to yet another embodiment of the present invention, the gate electrode 17 may be formed as a stacked structure of heterogeneous materials, but the gate electrode 17 may further include a barrier layer between the upper gate electrode and the lower gate electrode.

Subsequently, a capping dielectric material 18A may be formed over the gate electrode 17. The capping dielectric material 18A may be formed to have a sufficient height to fill the remaining portion of the gate trench 15 over the gate electrode 17. The capping dielectric material 18A may be formed over the gate electrode 17 and over the first hard mask layer 14. For example, the capping dielectric material 18A may include silicon nitride. According to another embodiment of the present invention, the capping dielectric material 18A may include a NON (Nitride-Oxide-Nitride) multi-layer structure.

Referring to FIGS. 4A and 4B, a gate capping layer 18 that gap-fills the remaining portion of the gate trench 15 may be formed over the gate electrode 17. To this end, a Chemical Mechanical Polishing (CMP) process or a cleaning process using the upper surface of the first hard mask layer 14 as an etch stop target may be performed.

Subsequently, a first impurity region 19 and a second impurity region 20 may be formed. The first and second impurity regions 19 and 20 may be formed by a doping process, such as an implantation process. Hereinafter, the first and second impurity regions 19 and 20 may be referred to as ‘first and second source/drain regions 19 and 20’. The first source/drain region 19 and the second source/drain region 20 may have the same depth. According to another embodiment of the present invention, the first source/drain region 19 may be deeper than the second source/drain region 20. The first source/drain region 19 may be a region to which a bit line contact is coupled. The second source/drain region 20 may be a region to which a storage contact is coupled.

A cell transistor of a memory cell may be formed by the gate electrode 17, the first source/drain region 19, and the second source/drain region 20.

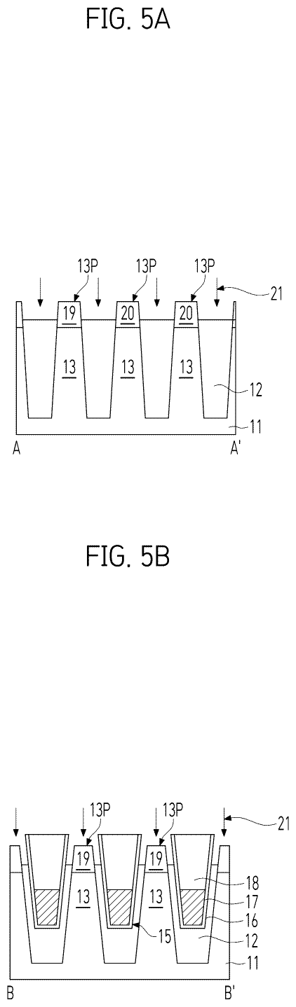

Referring to FIGS. 5A and 5B, the first hard mask layer 14 may be removed. Subsequently, a recess process 21 may be performed onto the isolation layer 13.

The removal of the first hard mask layer 14 and the recess process 21 of the isolation layer 13 may be performed as a cleaning process. For example, the cleaning process may include a wet cleaning process or a dry cleaning process. For example, the wet cleaning process may be performed by using a hydrogen fluoride (HF) solution.

As the isolation layer 13 is recessed to a predetermined depth, the upper surface of the active region 13 may be disposed at a higher level than the upper surface of the isolation layer 12. The active region 13 disposed at a higher level than the upper surface of the isolation layer 12 may be referred to as an active region protrusion 13P. The active region protrusion 13P may include first and second source/drain regions 19 and 20. Also, the upper surface of the gate capping layer 18 may also be disposed at a higher level than the upper surface of the isolation layer 12.

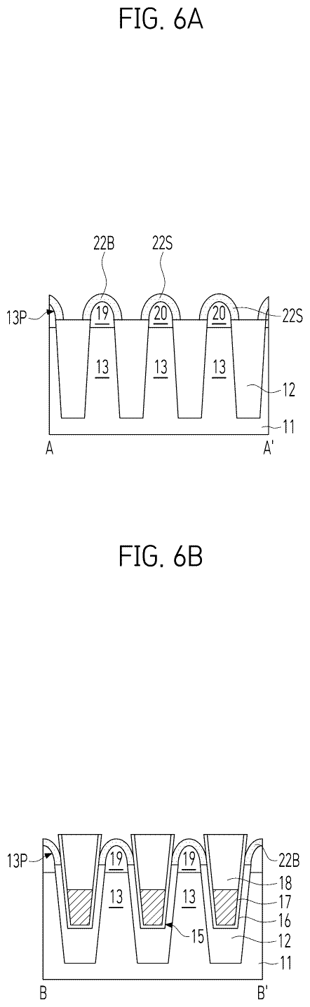

Referring to FIGS. 6A and 6B, the first and second pads 22B and 22S covering the active region protrusion 13P may be formed over the active region protrusion 13P. The first and second pads 22B and 22S may be SEG materials that are formed by a Selective Epitaxial Growth (SEG) process. For example, the first and second pads 22B and 22S may be doped SEG materials.

As the first and second pads 22B and 22S are formed to cover the active region protrusion 13P, the effect of increasing the line width of the active region protrusion 13P may be obtained. Since the first and second pads 22B and 22S respectively cover the sidewall and upper surface of the active region protrusion 13P, the line width may be increased twice as much as the thickness of each pad 22B and 22S, and the height may be increased as much as the thickness of each pad 22B and 22S.

Therefore, the contact margin (or landing margin) between a contact and the substrate 11 may be secured during the subsequent process of forming the contact. Also, since the contact etching depth is decreased by as much as the height of each pad 22B and 22S during the process of etching the contact hole for the contact to be formed subsequently, it is possible to prevent a decrease in the process margin and the not-open phenomenon of the contact hole.

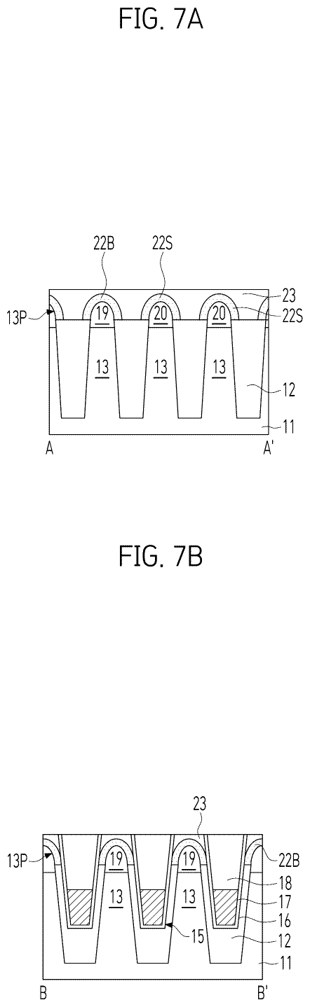

Referring to FIGS. 7A and 7B, a low-k layer 23 may be formed between the first pad 22B and the second pad 22S. The low-k layer 23 may gap-fill between the neighboring buried gate structures over the first pad 22B. The low-k layer 23 may have an upper surface at the same level as the upper surface of the gate capping layer 18. The upper surface of the low-k layer 23 may be disposed at a higher level than the upper surfaces of the first and second pads 22B and 22S.

The low-k layer 23 may have a lower dielectric constant than silicon nitride (Si₃N₄). The low-k layer 23 may include a material layer whose dielectric constant is less than approximately 3.9. For example, the low-k layer 23 may include SiCO.

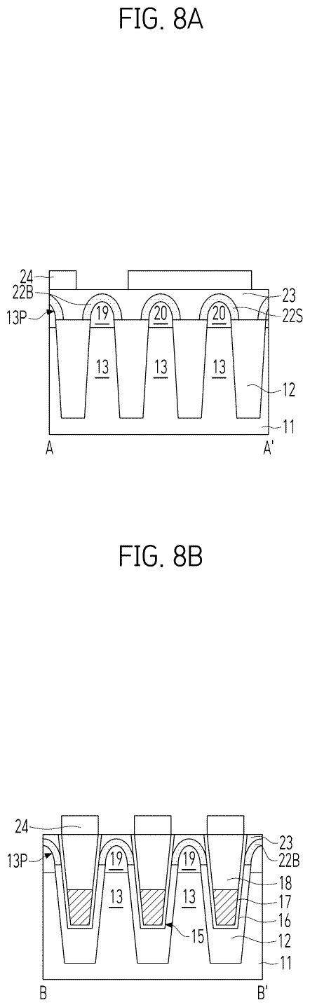

Referring to FIGS. 8A and 8B, a second hard mask layer 24 may be formed over the low-k layer 23 and the gate capping layer 18. The second hard mask layer 24 may be applied as an inter-layer dielectric layer. The second hard mask layer 24 may include a dielectric material. For example, the second hard mask layer 24 may include silicon oxide, but the embodiments of the present invention are not limited thereto. The second hard mask layer 24 may be patterned to define a first contact hole region.

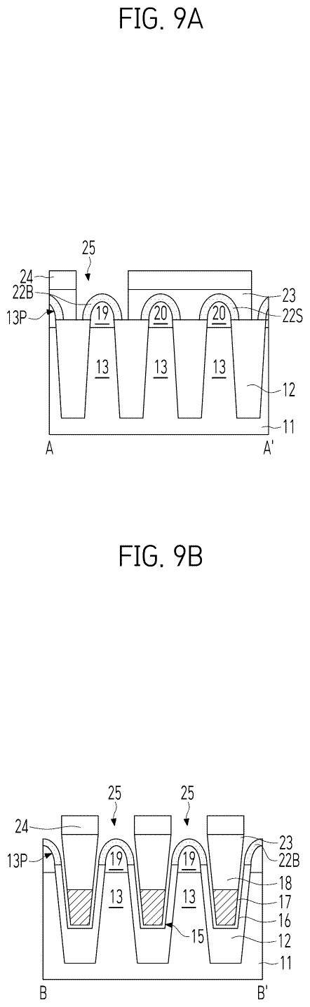

Referring to FIGS. 9A and 9B, the low-k layer 23 exposed by the second hard mask layer 24 may be etched to form the first contact hole 25. When the low-k layer 23 is etched, the first pad 22B may remain intact or substantially as it was without being lost due to the etching selectivity.

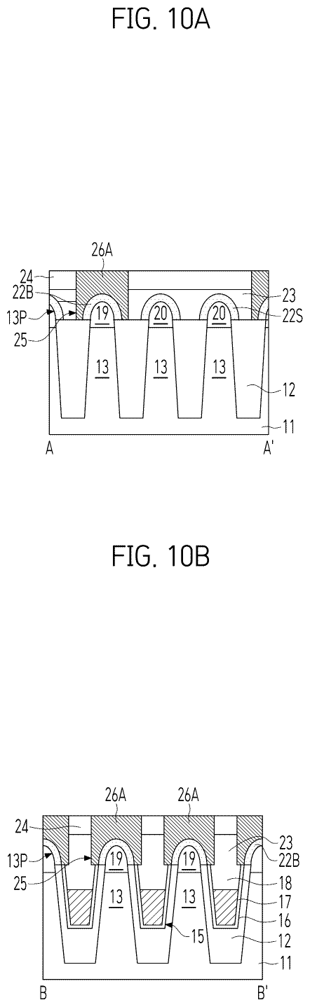

Referring to FIGS. 10A and 10B, a preliminary first contact 26A gap-filling the first contact hole 25 (see FIGS. 9A and 9B) may be formed. The preliminary first contact 26A may be formed by a selective epitaxial growth (SEG) process. For example, the preliminary first contact 26A may include SEG SiP. In this way, the preliminary first contact 26A may be formed without a void by the selective epitaxial growth process. According to another embodiment of the present invention, the preliminary first contact 26A may be formed by depositing polysilicon deposition and performing a Chemical Mechanical Polishing (CMP) process. The preliminary first contact 26A may fill the first contact hole 25 (see FIGS. 9A and 9B). The upper surface of the preliminary first contact 26A may be disposed at the same level as the upper surface of the second hard mask layer 24.

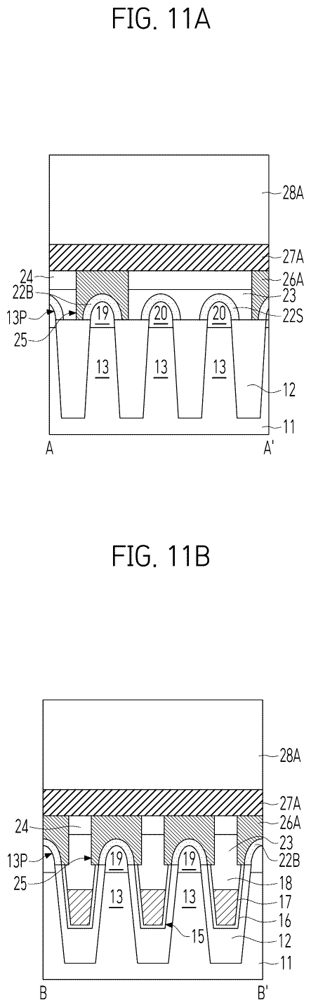

Referring to FIGS. 11A and 11B, a conductive layer 27A and a hard mask material layer 28A may be sequentially stacked over the preliminary first contact 26A and the second hard mask layer 24. The conductive layer 27A may include a metal-containing material. The conductive layer 27A may include a metal, a metal nitride, a metal silicide, or a combination thereof. According to an embodiment of the present invention, the conductive layer 27A may include tungsten (W). According to another embodiment of the present invention, the conductive layer 27A may include a stack of titanium nitride and tungsten (TiN/W). In this case, the titanium nitride may serve as a barrier. The hard mask material layer 28A may be formed of a dielectric material having an etching selectivity with respect to the conductive layer 27A and the preliminary first contact 26A. The hard mask material layer 28A may include silicon oxide or silicon nitride.

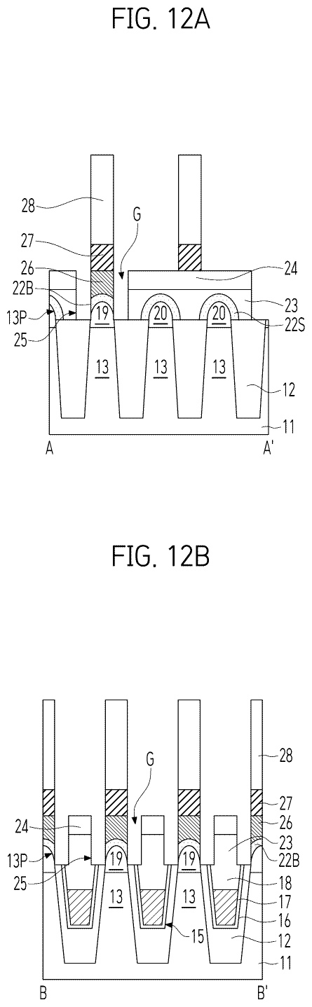

Referring to FIGS. 12A and 12B, a first contact 26, a conductive line 27, and a conductive line hard mask 28 may be formed.

To this end, a mask pattern may be formed over the hard mask material layer 28A (see FIGS. 11A and 11B), and then the hard mask material layer 28A, the conductive layer 27A (see FIGS. 11A and 11B), and the preliminary first contact 26A (see FIGS. 11A and 11B) may be sequentially etched by using the mask pattern. When the preliminary first contact 26A is etched, the first pad 22B may also be etched together.

The first pad 22B, the first contact 26, the conductive line 27, and the conductive line hard mask 28 may have the same line width. The first pad 22B, the first contact 26, the conductive line 27, and the conductive line hard mask 28 may be referred to as a ‘bit line pad 22B’, a ‘bit line contact 26’, a ‘bit line 27’, and a ‘bit line hard mask 28’, respectively. The bit line 27 and the bit line hard mask 28 may be referred to as a bit line structure.

The line width of the bit line structure may be less than the diameter of the first contact hole 25 leaving a gap G around the first contact 26. The gap G may be formed not in a surrounding shape surrounding the first contact 26, but in an independent form on both sidewalls of the bit line contact 21. As a result, one first contact 26 and a pair of gaps G may be disposed in the first contact hole 25. The pair of gaps G may be separated from each other by the first contact 26.

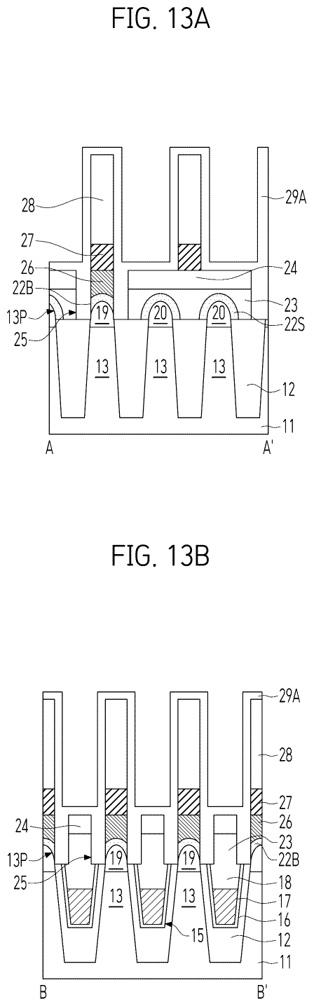

Referring to FIGS. 13A and 13B, a spacer layer 29A may be formed. The spacer layer 29A may gap-fill between the gaps G (see FIGS. 12A and 12B) and cover both sidewalls and the upper portion of the bit line structure. The spacer layer 29A may include a single layer. The spacer layer 29A may include, for example, silicon nitride.

According to another embodiment of the present invention, the spacer layer 29A may include a multi-layer structure including two or more layers made of a material selected from the group including silicon nitride, silicon oxide, silicon oxynitride, low-k materials, and combinations thereof.

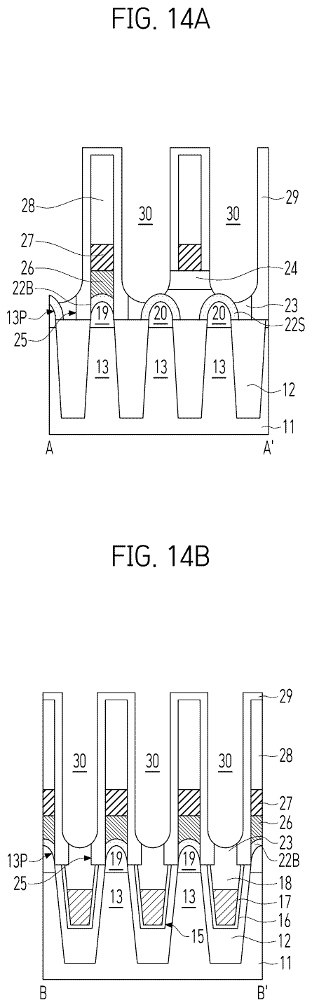

Referring to FIGS. 14A and 14B, spacers 29 may be formed. The spacers 29 may include a spacer 29 gap-filling the first contact hole 25 and a spacer 29 disposed on the sidewalls of the conductive line 27 and the conductive line hard mask 28. The spacer 29 gap-filling the first contact hole 25 may be referred to as a ‘gap-fill spacer’. The spacer 29 disposed on the sidewalls of the conductive line 27 and the conductive line hard mask 28 may be referred to as a ‘bit-line spacer’. The bit line spacer may be formed as a single layer or multiple layers. According to another embodiment of the present invention, the spacers 29 may further include a low-k material or an air gap.

Subsequently, a second contact hole 30 may be formed. The second contact hole 30 may be disposed between the neighboring conductive structures. The second contact hole 30 exposing the second pad 22S may be formed by etching the second hard mask layer 24 and the low-k layer 23 between the spacers 29, that is, between the neighboring conductive structures. By forming the second pad 22S in advance before the second contact hole 30 is formed, the contact etching height may be decreased by as much as the thickness of the second pad 22S, and also the contact margin (or landing margin) between the second impurity region 20 and the subsequent second contact may be secured by as much as the thickness of the second pad 22S.

The second contact hole 30 may have a line type extending in the second direction D2. The second contact holes 30 may be spaced apart from each other by a conductive structure.

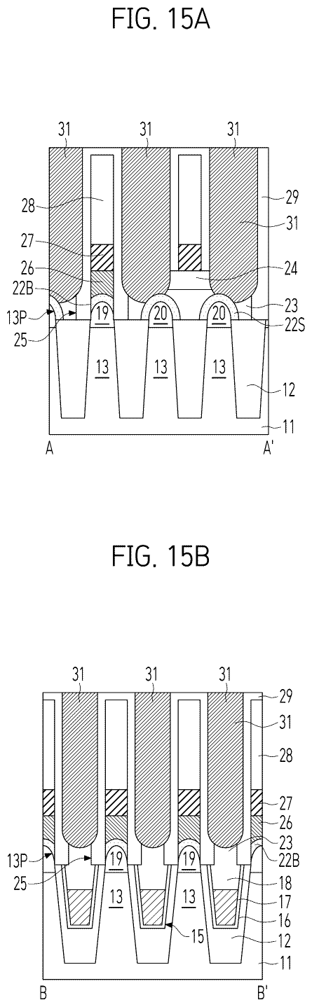

Referring to FIGS. 15A and 15B, a second contact 31 gap-filling the second contact hole 30 may be formed. The second contact 31 may be coupled to the second impurity region 20 through the second pad 22S.

The second contact 31 may be formed through a series of processes of forming a plug material layer that gap-fills the second contact hole 30, performing an etching process in such a manner that the plug material layer is separated and spaced apart from each other in the second direction D2 (see FIG. 1) to form a plug isolation portion, and then forming an isolation layer that gap-fills the plug isolation portion.

The second contact 31 may have a pillar shape. The second contact 31 may be disposed over the second pad 22S. The second contact 31 may be coupled to the second impurity region 20 through the second pad 22S. The second pad 22S may improve the contact margin between the second contact 31 and the second impurity region 20. The second contact 31 may include a conductive material. For example, the conductive material may include a semiconductor material or a metal material. For example, the semiconductor material may include polysilicon. For example, the metal material may include tungsten (W). According to another embodiment of the present invention, the second contact 31 may include a stacked structure of a semiconductor material and a metal material. According to yet another embodiment of the present invention, the second contact 31 may include a stacked structure of a semiconductor material, an ohmic contact layer, and a metal material. The second contact 31 may be referred to as a ‘storage node contact 31’.

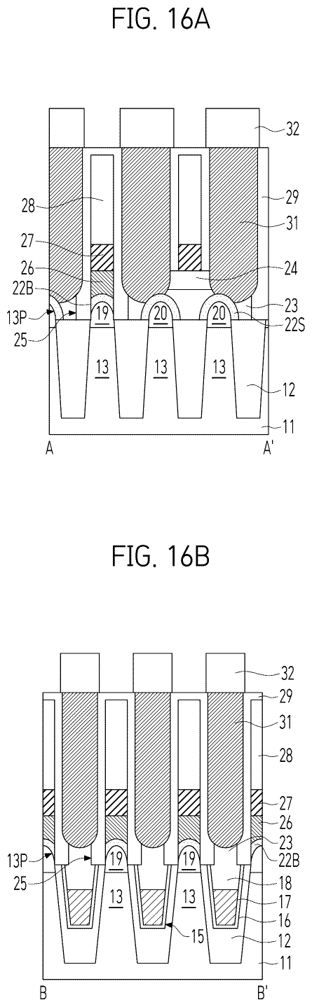

Referring to FIGS. 16A and 16B, a memory element 32 may be formed over the second contact 31. The memory element 32 may include a capacitor including a storage node. The storage node may include a pillar shape, but the embodiments of the present invention are not limited thereto. Although not illustrated, a dielectric layer and a plate node may be further formed over the storage node. The storage node may have a cylinder shape other than the pillar shape. According to another embodiment of the present invention, a landing pad may be disposed between the second contact 31 and the memory element 32. The landing pads may be spaced apart from each other by an inter-layer dielectric layer.

According to another embodiment of the present invention, diverse memory elements may be coupled to the second contact 31 over the second contact 31.

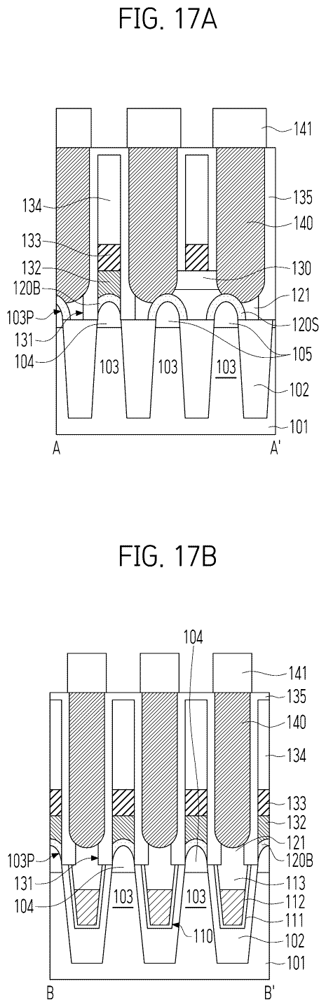

FIGS. 17A and 17B are cross-sectional views illustrating the semiconductor device in accordance with another embodiment of the present invention. FIGS. 17A and 17B are mostly the same as FIGS. 2A and 2B except for the structures of the gate capping layer and the low-k layer. The same reference numerals are given to the same structures, and for the sake of convenience in description, the description on the same structures may be omitted or simplified.

As illustrated in FIGS. 1, 17A and 17B, referring to FIGS. 1, 2A and 2B, the semiconductor device may include a plurality of memory cells. Each memory cell may include conductive structures disposed at different levels. For example, each memory cell may include a cell transistor including a buried word line WL, a bit line BL 133, and a memory element 141 (see FIGS. 17A and 17B).

An isolation layer 102 and an active region 103 may be formed in the substrate 101. A plurality of active regions 103 may be defined by the isolation layer 102. Each active region 103 may include a protrusion 103P disposed at a level higher than the upper surface of the isolation layer 102.

A line-shaped buried word line WL extending in the first direction D1 may be formed over the substrate 101. The buried word line WL may be formed as a buried gate structure. The buried gate structure may include a gate electrode 112 and a gate capping layer 113 formed over a gate dielectric layer 111. The buried gate structure may be formed to fill the gate trench 110 over the surface of the gate dielectric layer 111.

The gate dielectric layer 111 may be formed on the surface of the gate trench 110. The gate electrode 112 may be formed over the gate dielectric layer 111 to fill a lower portion of the gate trench 110. The gate capping layer 113 may be formed over the gate electrode 112 to fill the remaining portion of the gate trench 110. The upper surface of the gate capping layer 113 may be disposed at the same level as the upper surface of the isolation layer 102.

First and second impurity regions 104 and 105 may be formed over the substrate 101. The first and second impurity regions 104 and 105 may be referred to as ‘first and second source/drain regions’. The first and second impurity regions 104 and 105 may be formed in the active region protrusion 103P.

The first and second pads 120B and 120S may be formed over the first and second impurity regions 104 and 105, respectively. The first and second pads 120B and 120S may be applied to secure the contact margin with the substrate during the subsequent contact process. The first pad 120B may be disposed over the first impurity region 104. The second pad 120S may be disposed over the second impurity region 105.

The first and second pads 120B and 120S may include a semiconductor material. The first and second pads 120B and 120S may be selective epitaxial growth (SEG) layers. The first and second pads 120B and 120S may be doped SEG materials. The first and second pads 120B and 120S may be formed simultaneously through a one-time process.

A low-k layer 121 may be disposed over the isolation layer between the first pad 120B and the second pad 120S and over the gate capping layer 113 between the neighboring first pads 120B. The low-k layer 121 may have a dielectric constant which is less than the dielectric constant of silicon nitride (Si₃N₄). The low-k layer 121 may include a material layer whose dielectric constant is less than approximately 3.9. For example, the low-k layer 121 may include SiCO. The low-k layer 121 may also be disposed over the first and second pads 120B and 120S. The upper surface of the low-k layer 121 may be disposed at a higher level than the upper surfaces of the first and second pads 120B and 120S.

A hard mask 130 may be formed over the low-k layer 121 between the first pad 120B and the second pad 120S. The hard mask 130 may serve as an etching mask for forming a first contact hole 131. The hard mask 130 may include a material having an etching selectivity with respect to the low-k layer 121. The hard mask 130 may be disposed below the first conductive line 133 disposed between the second contacts 140.

A first contact 132 may be formed over the first pad 120B. The first contact 132 may be coupled to the first impurity region 104 through the first pad 120B. The first pad 120B may improve the contact margin between the first contact 132 and the first impurity region 104. The first pad 120B may have the same line width as the line width of the first contact 132 and have both sidewalls aligned in a direction perpendicular to the substrate. The first contact 132 may be disposed in the first contact hole 131 having the lower surface at a level lower than the upper surface of the active region 103. A portion of the first contact 132 may have a line width which is less than the diameter of the first contact hole 131. The first contact 132 may include a conductive material. For example, the first contact 132 may be formed of polysilicon or a metal material. The first contact 132 may be referred to as a ‘bit line contact 132’. The first pad 120B may be referred to as a ‘bit line contact pad 120B’.

A conductive structure may be formed over the first contact 132. The conductive structure may be referred to as a ‘bit line structure’. The conductive structure may include a stacked structure of a conductive line 133 and a conductive line hard mask 134. The conductive line 133 may be coupled to the first impurity region 104 by the first contact 132 and the first pad 120B.

The conductive line 133 and the conductive line hard mask 134 may be referred to as ‘a bit line 133’ and ‘a bit line hard mask 134,’ respectively. The conductive line 133 may correspond to the bit line BL illustrated in FIG. 1.

Spacers 135 may be formed on the sidewalls of the first pad 120B, the first contact 132, and the conductive structure. The spacers 135 may gap-fill the first contact hole 131, that is, on the sidewalls of the first pad 120B and the first contact 132, and may also be formed on the sidewalls of the conductive line 133 and the conductive line hard mask 134. The spacers 135 may be formed as a continuous single layer. The spacers 135 may include, for example, silicon nitride.

A second contact 140 may be disposed between the neighboring conductive structures. The second contact 140 may have a pillar shape. The second contact 140 may be disposed over the second pad 120S. The second contact 140 may be coupled to the second impurity region 105 through the second pad 120S. The second pad 120S may improve the contact margin between the second contact 140 and the second impurity region 105. The second contact 140 may be referred to as a ‘storage node contact 140’.

The spacers 135 and the low-k layer 121 may be disposed between the first pad 120B and the second pad 120S and between the first pads 120B. Therefore, it is possible to prevent the parasitic capacitance and leakage current between the conductive structure coupled to the first pad 120B and the second contact 140 coupled to the second pad 120S.

As described above, according to an embodiment of the present invention, it is possible to secure the contact margin (or landing margin) between each contact and the substrate 101 by disposing the first and second pads 120B and 120S below the first and second contacts 132 and 140. By forming the first and second pads 120B and 120S over the protrusions 130P of the active region to cover the active region protrusion 130P, the effect of increasing the line width of the active region may be obtained. Therefore, an overlap margin between the first and the second contacts 132 and 140 and the substrate may be secured after all. Also, since the etching height of the contact hole for forming each contact may be decreased by as much as the height of the first and second pads 120B and 120S, it is possible to prevent the not-open phenomenon of the contact hole and secure the process margin.

Also, according to an embodiment of the present invention, it is possible to prevent the parasitic capacitance and leakage current between the contacts and prevent a short between the contacts by applying the low-k layer 121 between the active region protrusion 130P and the first and second pads 120B and 120S and between the first pads 120B.

A memory element 141 may be formed over the second contact 140.

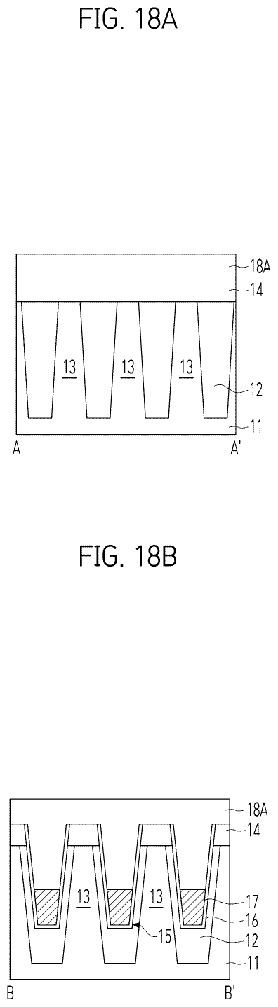

FIGS. 18A, 19A, 20A, 21A, 22A, 23A, 24A, 25A, 26A, 27A, 28A, 29A, 30A and 31A are cross-sectional views illustrating a method for fabricating the semiconductor device shown in FIG. 17A in accordance with another embodiment of the present invention. FIGS. 18B, 19B, 20B, 21B, 22B, 23B, 24B, 25B, 26B, 27B, 28B, 29B, 30B and 31B are cross-sectional views illustrating a method for fabricating the semiconductor device shown in FIG. 17B in accordance with another embodiment of the present invention.

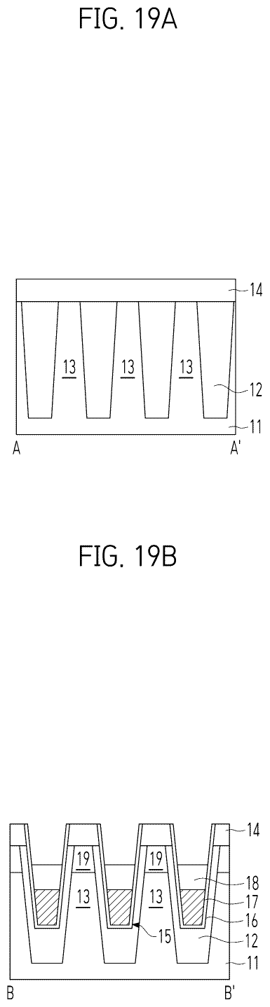

FIGS. 18A and 18B show the same process, only different in the directions of the cross-sectional views. Likewise, FIGS. 19A and 19B to 31A and 31B also show the same processes, only different in the directions of the cross-sectional views. To help understanding, the cross-sectional views of the same process will be described together. The processes of FIGS. 18A and 18B to 31A and 31B may be similar to the processes of FIGS. 3A and 3B to 16A and 16B, except for the processes of the gate capping layer and the low-k layer. The same reference symbol is given to the same structure, and for the sake of convenience in description, the description on the same structure and the same process will be omitted or provided briefly.

Referring to FIGS. 18A and 18B, an isolation layer 12 may be formed in the substrate 11. An active region 13 may be defined by the isolation layer 12.

Subsequently, a buried gate structure may be formed over the substrate 11. The buried gate structure may correspond to the word line WL illustrated in FIG. 1. The buried gate structure may include a gate trench 15, a gate dielectric layer 16 covering the lower surface and sidewalls of the gate trench 15, a gate electrode 17 filling a portion of the gate trench 15 over the gate dielectric layer 16, and a gate capping layer 18 (see FIG. 19B) formed over the gate electrode 17.

A method of forming the buried gate structure includes first forming the gate trench 15 in the substrate 11. The gate trench 15 may have a line shape that crosses the active region 13 and the isolation layer 12. The gate trench 15 may be formed by forming a mask pattern (not shown) over the substrate 11 and performing an etching process with the mask pattern used as an etching mask. To form the gate trench 15, a hard mask layer 14 may be used as an etching barrier.

Although not illustrated, a fin region may be formed after the gate trench 15 is formed. The fin region may be formed by recessing a portion of the isolation layer 12.

Subsequently, the gate dielectric layer 16 may be formed on the lower surface and sidewalls of the gate trench 15. Before the gate dielectric layer 16 is formed, the etching damage on the surface of the gate trench 15 may be recovered. For example, after a sacrificial oxide is formed by a thermal oxidation process, the sacrificial oxide may be removed.

The gate dielectric layer 16 may be formed by a thermal oxidation process. For example, the lower surface and sidewalls of the gate trench 15 may be oxidized to form the gate dielectric layer 16.

Subsequently, the gate electrode 17 may be formed over the gate dielectric layer 16. The gate electrode 17 may be formed by forming a conductive layer (not shown) to fill the gate trench 15 and then performing a recessing process. The recessing process may be performed by performing an etch-back process or by sequentially performing a Chemical Mechanical Polishing (CMP) process and an etch-back process. The gate electrode 17 may have a recessed shape that fills a portion of the gate trench 15. The upper surface of the gate electrode 17 may be disposed at a lower level than the upper surface of the substrate 11. The gate electrode 17 may include a metal, a metal nitride, or a combination thereof.

Subsequently, a capping dielectric material 18A may be formed over the gate electrode 17. The capping dielectric material 18A may be formed to have a sufficient height to fill the remaining portion of the gate trench 15 over the gate electrode 17. The capping dielectric material 18A may be formed over the gate electrode 17 and over the first hard mask layer 14.

Referring to FIGS. 19A and 19B, the gate capping layer 18 that gap-fills a portion of the gate trench 15 may be formed over the gate electrode 17. To this end, an etch-back process or a cleaning process may be performed on the capping dielectric material 18A (see FIGS. 18A and 18B).

The upper surface of the gate capping layer 18 may be disposed at a lower level than the upper surface of the isolation layer 12 and the upper surface of the active region, i.e., the first and second impurity regions 19 and 20.

Subsequently, the first impurity region 19 and the second impurity region 20 may be formed. The first and second impurity regions 19 and 20 may be formed by a doping process, such as an implantation process. Hereinafter, the first and second impurity regions 19 and 20 may be referred to as ‘first and second source/drain regions 19 and 20’. The first source/drain region 19 may be a region to which a bit line contact is to be coupled. The second source/drain region 20 may be a region to which a storage contact is to be coupled.

A cell transistor of a memory cell may be formed by the gate electrode 17, the first source/drain region 19, and the second source/drain region 20.

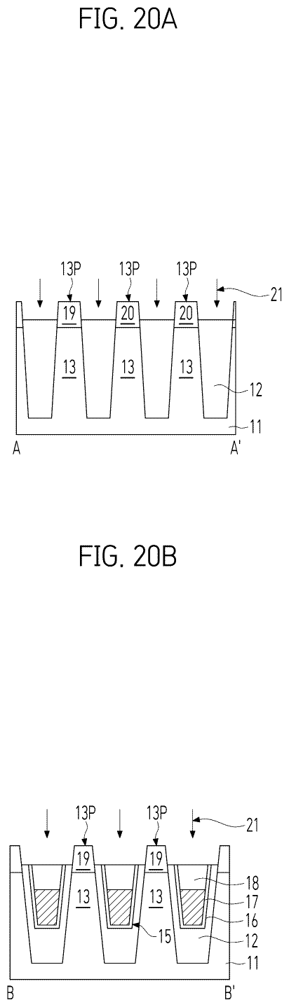

Referring to FIGS. 20A and 20B, the first hard mask layer 14 may be removed. Subsequently, a recess process 21 may be performed onto the isolation layer 13.

The removal of the first hard mask layer 14 and the recess process 21 of the isolation layer 13 may be performed as a cleaning process. For example, the cleaning process may include a wet cleaning process or a dry cleaning process. For example, the wet cleaning process may be performed using a hydrogen fluoride (HF) solution.

As the isolation layer 13 is recessed to a predetermined depth, the upper surface of the active region 13 may be disposed at a higher level than the upper surface of the isolation layer 13. The active region 13 disposed at a higher level than the upper surface of the isolation layer 13 may be referred to as an active region protrusion 13P. The active region protrusion 13P may include first and second source/drain regions 19 and 20. Also, the upper surface of the gate capping layer 18 may be disposed at a higher level than the upper surface of the isolation layer 13, but the embodiments of the present invention are not limited thereto.

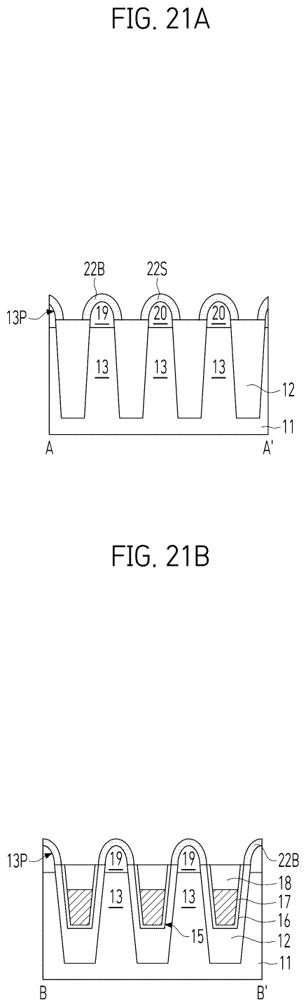

Referring to FIGS. 21A and 21B, first and second pads 22B and 22S covering the active region protrusion 13P may be formed over the active region protrusion 13P. The first and second pads 22B and 22S may be SEG materials that are formed by a selective epitaxial growth (SEG) process. For example, the first and second pads 22B and 22S may be doped SEG materials.

As the first and second pads 22B and 22S are formed to cover the active region protrusion 13P, the effect of increasing the line width of the active region protrusion 13P may be obtained. Since the first and second pads 22B and 22S cover the sidewall and upper surface of the active region protrusion 13P, respectively, the line width may be increased twice as much as the thickness of each pad 22B and 22S, and the height may be increased by as much as the thickness of each pad 22B and 22S.

Therefore, the contact margin (or landing margin) between the contact and the substrate 11 may be secured during the subsequent process of forming the contact. Also, since the contact etching depth is decreased by as much as the height of each pad 22B and 22S during the contact hole etching process for the subsequent contact, it is possible to prevent a decrease in the process margin and the not-open phenomenon of the contact hole.

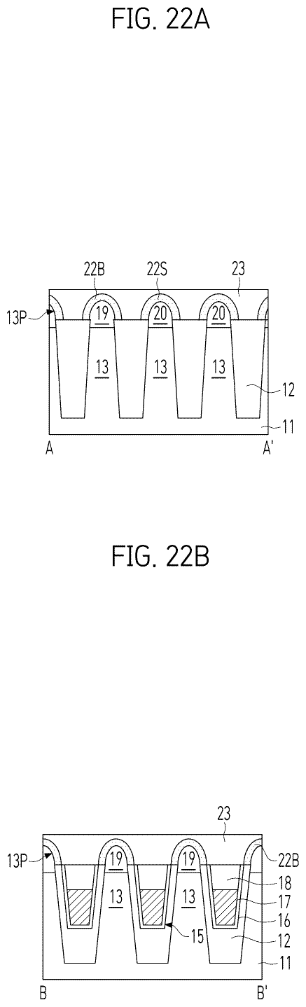

Referring to FIGS. 22A and 22B, a low-k layer 23 may be formed between the first pad 22B and the second pad 22S and between the first pads 22B. The upper surface of the low-k layer 23 may be disposed at a higher level than the upper surfaces of the first and second pads 22B and 22S.

The low-k layer 23 may have a dielectric constant which is less than the dielectric constant of silicon nitride (Si₃N₄). The low-k layer 23 may include a material layer whose dielectric constant is less than approximately 3.9. For example, the low-k layer 23 may include SiCO.

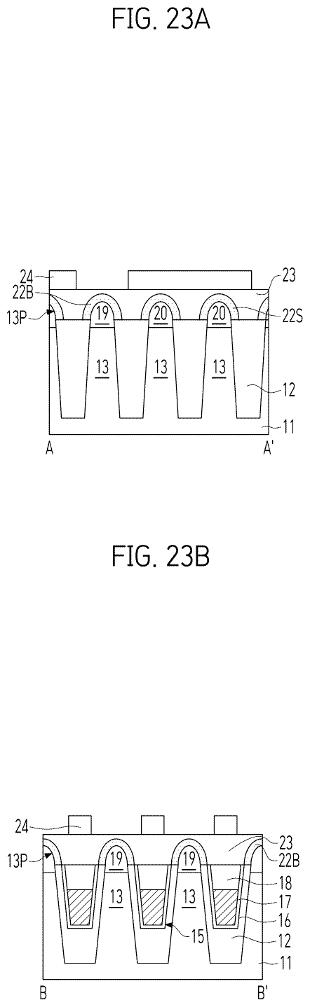

Referring to FIGS. 23A and 23B, a second hard mask layer 24 may be formed over the low-k layer 23 and the gate capping layer 18. The second hard mask layer 24 may be applied as an inter-layer dielectric layer. The second hard mask layer 24 may be patterned to define a first contact hole region.

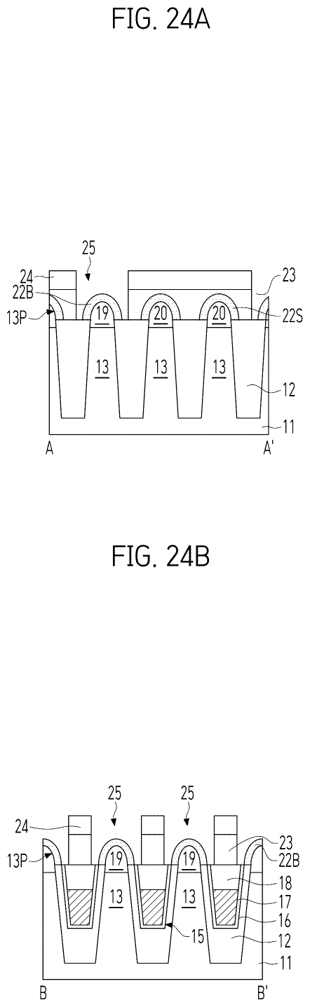

Referring to FIGS. 24A and 24B, the low-k layer 23 exposed by the second hard mask layer 24 may be etched to form a first contact hole 25. While the low-k layer 23 is etched, the first pad 22B may remain as it is without being lost due to the etching selectivity.

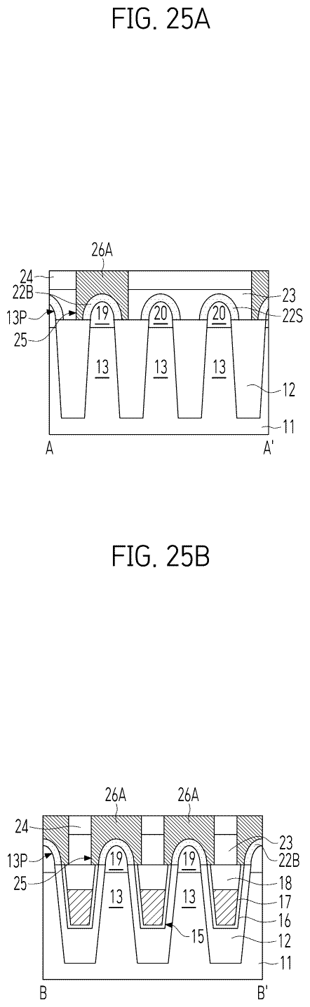

Referring to FIGS. 25A and 25B, a preliminary first contact 26A that gap-fills the first contact hole 25 (see FIGS. 24A and 24B) may be formed.

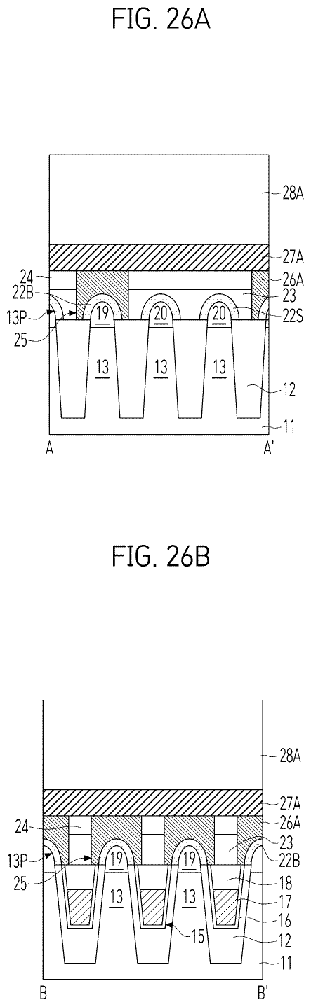

Referring to FIGS. 26A and 26B, a conductive layer 27A and a hard mask material layer 28A may be sequentially stacked over the preliminary first contact 26A and the second hard mask layer 24.

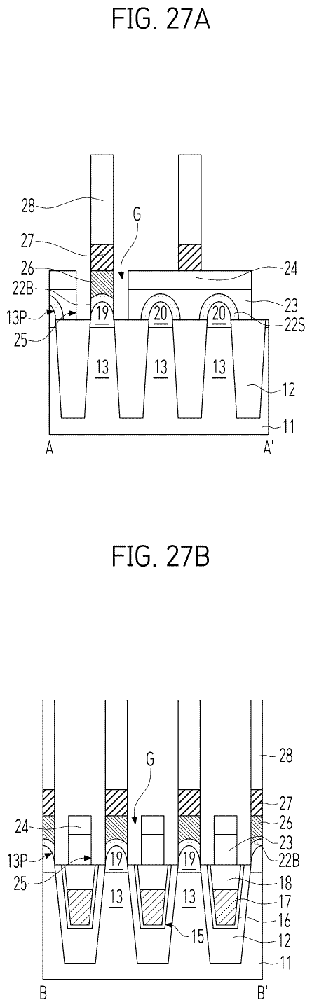

Referring to FIGS. 27A and 27B, a first contact 26, a conductive line 27, and a conductive line hard mask 28 may be formed.

To this end, a mask pattern may be formed over the hard mask material layer 28A (see FIGS. 11A and 11B), and the hard mask material layer 28A, the conductive layer 27A (see FIGS. 11A and 11B), and the preliminary first contact 26A (see FIGS. 11A and 11B) may be sequentially etched by using the mask pattern. When the preliminary first contact 26A is etched, the first pad 22B may also be etched together.

The first pad 22B, the first contact 26, the conductive line 27, and the conductive line hard mask 28 may have the same line width. The first pad 22B, the first contact 26, the conductive line 27, and the conductive line hard mask 28 may be referred to as a ‘bit line pad 22B’, a ‘bit line contact 26’, a ‘bit line 27’, and a ‘bit line hard mask 28’, respectively. The bit line 27 and the bit line hard mask 28 may be referred to as a bit line structure.

The line width of the bit line structure may be less than the diameter of the first contact hole 25. As a result, a gap G may be formed on the sidewalls of the first contact 26. The gap G may not have a surrounding shape surrounding the first contact 26. The gap G may include two separate gaps formed on both sidewalls of the bit line contact 21. In each contact hole 25, one first contact 26 and a pair of gaps G may be formed, with the pair of gaps G separated from each other by the first contact 26.

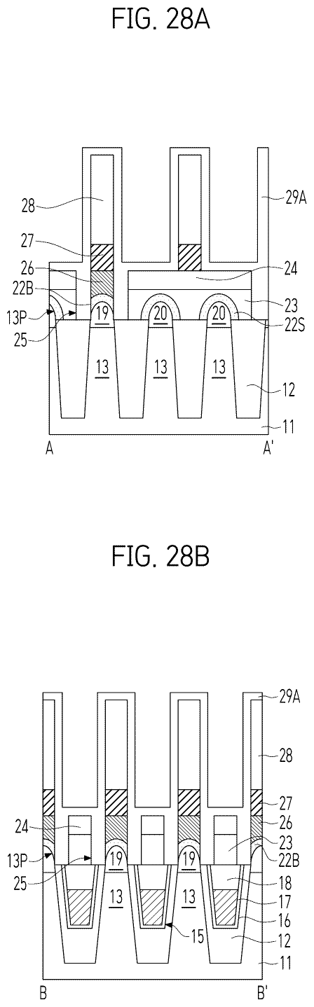

Referring to FIGS. 28A and 28B, a spacer layer 29A may be formed. The spacer layer 29A may gap-fill between the gaps G (see FIGS. 27A and 27B) and cover both sidewalls and the upper portion of the bit line structure. The spacer layer 29A may include a single layer. The spacer layer 29A may include, for example, silicon nitride.

According to another embodiment of the present invention, the spacer layer 29A may include a multi-layer structure including one selected from the group including silicon nitride, silicon oxide, silicon oxynitride, low-k materials, and combinations thereof.

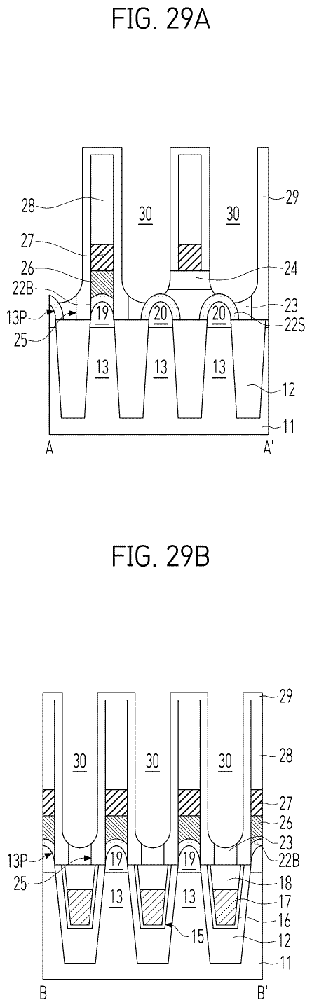

Referring to FIGS. 29A and 29B, spacers 29 may be formed. The spacers 29 may include a spacer 29 gap-filling the first contact hole 25, and a spacer 29 disposed on the sidewalls of the conductive line 27 and the conductive line hard mask 28. The spacer 29 gap-filling the first contact hole 25 may be referred to as a ‘gap-fill spacer’. The spacer 29 disposed on the sidewalls of the conductive line 27 and the conductive line hard mask 28 may be referred to as a ‘bit-line spacer’.

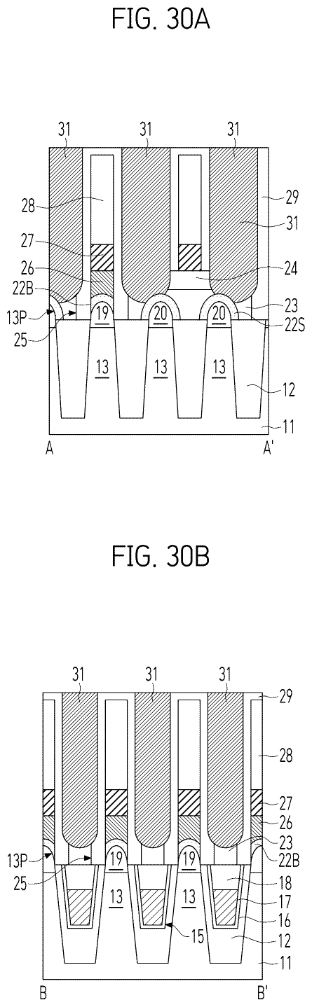

Subsequently, a second contact hole 30 may be formed. The second contact hole 30 may be disposed between the neighboring conductive structures. The second contact hole 30 may expose the second pad 22S. The second contact hole 30 may be formed by etching the second hard mask layer 24 and the low-k layer 23 between the spacers 29, that is, between the neighboring conductive structures. According to the illustrated embodiment of the present invention, by forming the second pad 22S in advance before the second contact hole 30 is formed, the contact etching height may be decreased by as much as the thickness of the second pad 22S, and also the contact margin (or landing margin) between the second impurity region 20 and the subsequently formed second contact 31 (see FIGS. 30A and 30B) may be secured by as much as the thickness of the second pad 22S.

The second contact hole 30 may have a line type extending in the second direction D2. The second contact holes 30 may be spaced apart from each other by the conductive structures.

Referring to FIGS. 30A and 30B, the second contact 31 that gap-fills the second contact hole 30 may be formed. The second contact 31 may be coupled to the second impurity region 20 through the second pad 22S.

The second contact 31 may be formed through a series of processes including forming a plug material layer that gap-fills the second contact hole 30, performing an etching process in such a manner that the plug material layer is separated and spaced apart from each other in the second direction D2 (see FIG. 1) to form a plug isolation portion, and then forming an isolation layer that gap-fills the plug isolation portion.

The second contact 31 may have a pillar shape. The second contact 31 may be disposed over the second pad 22S. The second contact 31 may be coupled to the second impurity region 20 through the second pad 22S. The second pad 22S may improve the contact margin between the second contact 31 and the second impurity region 20. The second contact 31 may be referred to as a ‘storage node contact 31’.

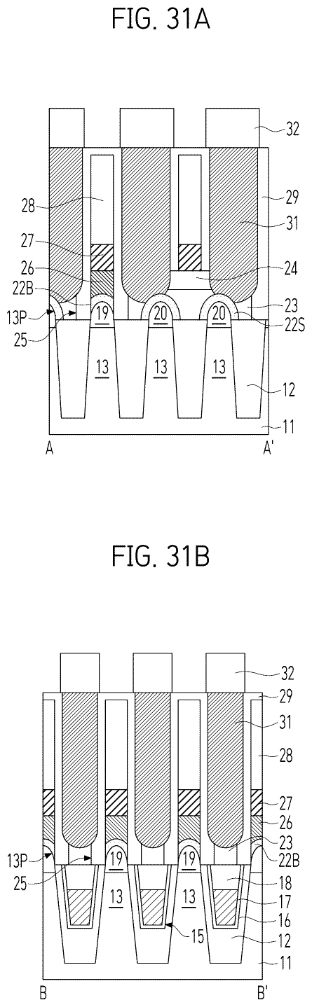

Referring to FIGS. 31A and 31B, a memory element 32 may be formed over the second contact 31. The memory element 32 may include a capacitor including a storage node. The storage node may include a pillar shape, but the embodiments of the present invention are not limited thereto. Although not illustrated, a dielectric layer and a plate node may be further formed over the storage node. The storage node may have a cylinder shape other than a pillar shape. According to another embodiment of the present invention, a landing pad may be disposed between the second contact 31 and the memory element 32. The landing pads may be spaced apart from each other by an inter-layer dielectric layer.

According to another embodiment of the present invention, diverse memory elements may be coupled to the second contact 31 over the second contact 31.

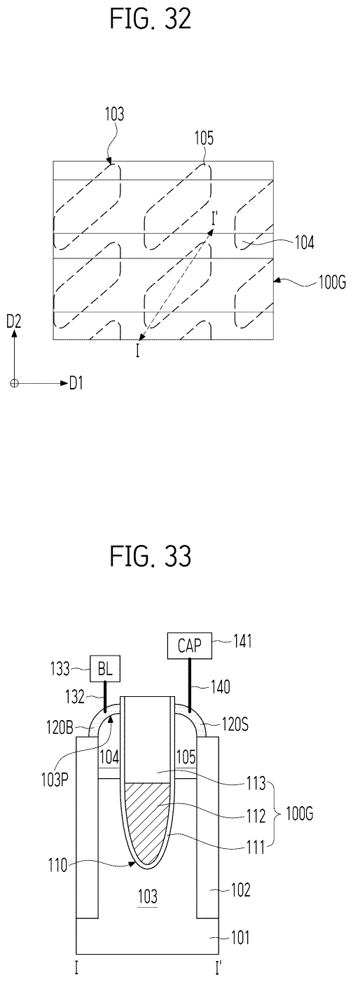

FIG. 32 is a plan view illustrating a semiconductor device in accordance with another embodiment of the present invention. FIG. 33 is a cross-sectional view illustrating the semiconductor device in accordance with another embodiment of the present invention. FIG. 33 is a cross-sectional view taken along a line I-I′ shown in FIG. 32.

Referring to FIGS. 32 and 33, the semiconductor device may include a substrate 101, a buried gate structure 100G, and first and second doped regions 104, and 105. The buried gate structure 100G, and the first and second doped regions 104, and 105, may be embedded in the substrate 101.

The semiconductor device may be a portion of a memory cell. For example, the semiconductor device may be a portion of a memory cell of a Dynamic Random Access Memory (DRAM). The semiconductor device may include a bit line 133 (see FIG. 33) and a memory storage element 141 (see FIG. 33) that are electrically connected to the substrate 101. The bit line 133 may be electrically connected to the first doped region 104 through the first contact 132. The memory storage element 141 may be electrically connected to the second doped region 105 through the second contact 140. The first contact 132 and the second contact 140 may be referred to as a ‘bit line contact’ and a ‘storage node contact,’ respectively. The bit line 133 and the memory storage element 141 may be disposed at a higher level than the buried gate structure 100G. The bit line 133 and the memory storage element 141 may be disposed at different levels. The memory storage element 141 may be disposed at a higher level than the bit line 133. The memory storage element 141 may include a capacitor. According to another embodiment of the present invention, the memory storage element 141 may be a thyristor, a phase-change material, a Magnetic Tunnel Junction (MTJ), or a variable resistance material.

An isolation layer 102 and an active region 103 may be formed over the substrate 101. A plurality of active regions 103 may be defined by the isolation layer 102. The isolation layer 102 may be a Shallow Trench Isolation (STI) region formed by a trench etching process. The isolation layer 102 may include silicon oxide, silicon nitride, or a combination thereof.

The active regions 103 may include strips arranged in the form of an array. The array of the active regions 103 may include a row array and/or a column array. The row array of the active regions 103 may include active regions 103 that are arranged in the first direction D1. The column array of the active regions 103 may include active regions 103 that are arranged in the second direction D2. From the perspective of a top view, the cross-section of each active region 103 may be a parallelogram, for example, a parallelogram with rounded edges.

Each active region 103 may have an upper surface at a higher level than the upper surface of the isolation layer 102. Each active region 103 may include a protrusion 103P disposed at a higher level than the upper surface of the isolation layer 102.

The substrate 101 may include a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include another semiconductor material such as germanium. The substrate 101 may include a III/V-group semiconductor substrate, for example, a compound semiconductor substrate, such as gallium arsenide (GaAs). The substrate 101 may include a Silicon-On-Insulator (SOI) substrate.

A line-shaped gate trench 110 may be formed in the substrate 101 in the first direction D1 to cross the active region 103 and the isolation layer 102. The gate trench 110 may cross the center of each active region 103. Therefore, the areas of both sides of the gate trench 110 in each active region 103, that is, the areas of the first doped region 104 and the second doped region 110, may be the same, but the embodiments of the present invention are not limited thereto.

The lower surface of the gate trench 110 may be disposed at a higher level than the lower surface of the isolation layer 102. The gate trench 110 may have a shallower depth than the isolation layer 102. The lower portion of the gate trench 110 may have a curvature. According to another embodiment of the present invention, the isolation layer 102 in the direction that the gate trench 110 extends may be etched to a predetermined depth to form a fin in the active region 103.

A gate dielectric layer 111 may be formed conformally on the surface of the gate trench 110. A gate electrode 112 filling a portion of the gate trench 110 may be formed over the gate dielectric layer 111. A gate capping layer 113 filling the remaining portion of the gate trench 110 may be formed over the gate electrode 112. The upper surface of the gate capping layer 113 may be disposed at a higher level than the upper surface of the isolation layer 102.

The gate dielectric layer 111 may be conformally formed on the lower surface and inner surfaces of the gate trench 110. The gate dielectric layer 111 may include silicon oxide, silicon nitride, silicon oxynitride, a high-k material, or a combination thereof. The high-k material may include a material whose dielectric constant is greater than the dielectric constant of silicon oxide. For example, the high-k material may include a material whose dielectric constant is greater than approximately 3.9. For another example, the high-k material may include a material whose dielectric constant is greater than approximately 10. For yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. Other known high-k materials may selectively be used as the high-k material. The gate dielectric layer 111 may include a metal oxide.

The gate electrode 112 may have a shape that fills the lower portion of the gate trench 110. The gate electrode 112 may be a low-resistance material to decrease the gate sheet resistance. The gate electrode 112 may include a semiconductor material, a metal-based material, or a combination thereof. The gate electrode 112 may include polysilicon, a metal, a metal nitride, or a combination thereof. For example, the gate electrode 112 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present invention, the gate electrode 112 may be formed of titanium nitride alone or molybdenum alone. According to yet another embodiment of the present invention, the gate electrode 112 may include a stack of titanium nitride and tungsten (i.e., TiN/W) or a stack of titanium nitride and polysilicon (i.e., TiN/Polysilicon).

According to another embodiment of the present invention, the gate electrode 112 may have a dual gate structure including an upper and a lower gate. According to yet another embodiment of the present invention, the gate electrode 112 may have a triple gate structure including upper, middle, and lower gates.

According to an embodiment of the present invention, the gate electrode 112 may have a high work function. The high work function may refer to a work function which is higher than the mid-gap work function of silicon. A low work function may refer to a work function which is lower than the mid-gap work function of silicon. For example, the high work function may have a work function which is higher than approximately 4.5 eV, and the low work function may have a work function which is lower than approximately 4.5 eV. The gate electrode 112 may include P-type polysilicon or nitrogen-rich titanium nitride (TiN).

According to an embodiment of the present invention, the gate electrode 112 may have an increased high work function. The gate electrode 112 may include a metal silicon nitride. The metal silicon nitride may be a metal nitride that is doped with silicon. The gate electrode 112 may include a metal silicon nitride having a controlled silicon content. For example, the gate electrode 112 may include tantalum silicon nitride (TaSiN) or titanium silicon nitride (TiSiN). Titanium nitride may have a high work function, and silicon may be contained in the titanium nitride to further increase the work function of the titanium nitride. The silicon content of the titanium silicon nitride may be adjusted to have an increased high work function. In an embodiment, the gate electrode 112 may include titanium aluminum nitride (TiAlN).

The gate capping layer 113 may serve to protect the gate electrode 112. The gate capping layer 113 may fill the upper portion of the gate trench 110 over the gate electrode 112. The gate capping layer 113 may include a dielectric material. The gate capping layer 113 may include silicon nitride, silicon oxynitride, or a combination thereof. According to another embodiment of the present invention, the gate capping layer 113 may include a combination of silicon nitride and silicon oxide. The gate capping layer 113 may include a silicon nitride liner and a spin-on dielectric (SOD) material.

First and second impurity regions 104 and 105 may be formed in the active region 103. The first impurity region 104 may be formed in the active region 103 on a first side of the buried gate structure 100G, and the second impurity region 105 may be formed in the active region 103 on a second side of the buried gate structure 100G. The first and second impurity regions 104 and 105 may be regions doped with a conductive dopant. For example, the doped dopant may include phosphorus (P), arsenic (As), antimony (Sb), or boron (B). The first impurity region 104 and the second impurity region 105 may be disposed in the active regions 103 on both sides of the gate trench 110, respectively. The first and second impurity regions 104 and 105 may be spaced apart from each other by the gate trench 110. The first and second impurity regions 104 and 105 may be referred to as ‘first and second source/drain regions,’. The first and second impurity regions 104 and 105 may be formed in the active region protrusion 103P.The lower portions of the first and second impurity regions 104 and 105 may be disposed at a higher level than the upper surface of the gate electrode 112, but the embodiments of the present invention are not limited thereto. The gate electrode 112, and the first and second impurity regions 104 and 105 may become a cell transistor. The cell transistor may improve the short channel effect by the gate electrode 112 having a buried gate structure.

The first and second pads 120B and 120S may be formed over the first and second impurity regions 104 and 105, respectively. The first and second pads 120B and 120S may be applied to secure the contact margin with the substrate during the process of forming the first and second contacts 132 and 140. The first pad 120B may be disposed over the first impurity region 104. The second pad 120S may be disposed over the second impurity region 105.

The first and second pads 120B and 120S may include a semiconductor material. The first and second pads 120B and 120S may be selective epitaxial growth (SEG) layers. The first and second pads 120B and 120S may be doped SEG materials. The first and second pads 120B and 120S may be formed simultaneously through a one-time process.

The first contact 132 may be formed over the first pad 120B. The first contact 132 may be coupled to the first impurity region 104 through the first pad 120B. The first pad 120B may improve the contact margin between the first contact 132 and the first impurity region 104. The first contact 132 may include a conductive material. For example, the first contact 132 may be formed of polysilicon or a metal material. The first contact 132 may be referred to as a ‘bit line contact 132’. The first pad 120B may be referred to as a ‘bit line contact pad 120B’.

The second contact 140 may be formed over the second pad 120S. The second contact 140 may be coupled to the second impurity region 105 through the second pad 120S. The second pad 120S may improve the contact margin between the second contact 140 and the second impurity region 105. The second contact 140 may include a conductive material. For example, the conductive material may include a semiconductor material or a metal material. For example, the semiconductor material may include polysilicon. For example, the metal material may include tungsten (W). According to another embodiment of the present invention, the second contact 140 may include a stacked structure of a semiconductor material and a metal material. According to yet another embodiment of the present invention, the second contact 140 may include a stacked structure of a semiconductor material, an ohmic contact layer, and a metal material. The second contact 140 may be referred to as a ‘storage node contact 140’. The second pad 120S may be referred to as a ‘storage node contact pad 120S’.

As described above, according to an embodiment of the present invention, it is possible to secure the contact margin (or landing margin) between each contact and the substrate 101 by disposing the first and second pads 120B and 120S below the first and second contacts 132 and 140. By forming the first and second pads 120B and 120S over the active region protrusion 130P to cover the active region protrusion 130P, the effect of increasing the line width of the active region may be obtained. Therefore, it is possible to secure the overlap margin between the first and second contacts 132 and 140 and the substrate. Also, since the etching height of the contact hole for forming each contact may be decreased by as much as the height of the first and second pads 120B and 120S, it is possible to prevent the not-open phenomenon of the contact hole and secure the process margin.

Referring to FIGS. 32 and 33, the semiconductor device may include a plurality of memory cells, and the neighboring memory cells may be separated from each other by the isolation layer 102. One memory cell may be formed over one active region 103, and this may be referred to as a memory cell of a ‘1G1A (one Gate-one Active) structure.’ In the memory cell of the 1G1A structure, the bit line 133 may be coupled to one active region 103. Therefore, one memory cell may be coupled to one bit line 133. The memory cell of the 1G1A structure may include 1T1C (one Transistor-one Capacitor). As a comparative example, in a typical DRAM, two memory cells may be formed in one active region, and two gate electrodes may be formed in one active region, and two neighboring memory cells may share one bit line.

According to the embodiments of the present invention, there is an effect of securing the contact margin by applying a free pad to a bit line contact and a storage node contact region.

According to the embodiments of the present invention, there is an effect of improving the electrical characteristics of a device by applying a low-k layer as a gap-fill material between the free pads.

While the present invention has been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a semiconductor substrate;
an active region including an isolation layer formed in the semiconductor substrate and a protrusion defined by the isolation layer, and disposed at a higher level than an upper surface of the isolation layer;
first and second pads suitable for covering the protrusion of the active region;
a first contact formed in an upper portion of the first pad and a conductive structure in an upper portion of the first contact; and
a second contact formed in an upper portion of the second pad.

2. The semiconductor device of claim 1, further comprising:
a low-k layer suitable for gap-filling an upper portion of the isolation layer between the first pad and the second pad.

3. The semiconductor device of claim 2, wherein the low-k layer has an upper surface at a higher level than upper surfaces of the first and second pads.

4. The semiconductor device of claim 2, wherein the low-k layer includes
a material whose dielectric constant is smaller than a dielectric constant of silicon nitride.

5. The semiconductor device of claim 2, wherein the low-k layer includes SiCO.

6. The semiconductor device of claim 1, wherein the first and second pads are selective epitaxial growth layers.

7. The semiconductor device of claim 1, wherein each of the first and second pads covers a side surface and an upper surface of the protrusion of the active region.

8. The semiconductor device of claim 1, further comprising:
a buried gate structure formed in the substrate and including a stacked structure of a gate electrode and a gate capping layer.

9. The semiconductor device of claim 1, wherein the protrusion of the active region includes a first impurity region and a second impurity region.

10. The semiconductor device of claim 1, wherein the first pad covers a first impurity region, and the second pad covers a second impurity region.

11. The semiconductor device of claim 1, wherein the first pad, the first contact, and the conductive structure have the same line width.

12. The semiconductor device of claim 1, wherein the first contact includes a bit line contact, and the conductive structure includes a bit line structure.

13. The semiconductor device of claim 1, wherein the second contact includes a storage node contact.

14. The semiconductor device of claim 1, further comprising:
a memory element in an upper portion of the second contact.

15. A semiconductor device comprising:
a semiconductor substrate;
an active region including an isolation layer which is formed in the semiconductor substrate and a protrusion which is defined by the isolation layer, spaced apart from another protrusion by the isolation layer, and disposed at a higher level than an upper surface of the isolation layer;
a buried gate structure formed in the semiconductor substrate to cross the isolation layer and the active region and have an upper surface at a lower level than the protrusion of the active region;
first and second pads suitable for covering the protrusion of the active region;
a first contact formed in an upper portion of the first pad and a conductive structure in an upper portion of the first contact; and
a second contact formed in an upper portion of the second pad.

16. The semiconductor device of claim 15, further comprising:
a low-k layer suitable for gap-filling an upper portion of the isolation layer between the first pad and the second pad and an upper portion of the buried gate structure between the first pads.

17. The semiconductor device of claim 16, wherein the low-k layer has an upper surface at a higher level than upper surfaces of the first and second pads.

18. The semiconductor device of claim 15, wherein the first and second pads include a doped Selective Epitaxial Growth (SEG) material.

19. The semiconductor device of claim 15, wherein each of the first and second pads covers a side surface and an upper surface of the protrusion of the active region.

20. The semiconductor device of claim 15, wherein the protrusion of the active region includes a first impurity region and a second impurity region.

21. The semiconductor device of claim 15, wherein the first pad covers the first impurity region, and the second pad covers the second impurity region.
